(19) United States
(12) Patent Application Publication
(10) Pub. No.: US 2009/0170313 A1
(43) Pub. Date: Jul. 2, 2009

(54) Method for Manufacturing Semiconductor Device

(76) Inventor: Soon Wook Jung, Bucheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/251,769

(22) Filed: Oct. 15, 2008

(30) Foreign Application Priority Data
Dec. 27, 2007 (KR) 10-2007-0138914

(51) Int. Cl. H01L 21/44

(52) U.S. Cl. 438/667; 257/E21.476

(57) ABSTRACT

A semiconductor device and method for manufacturing the same are provided. A dielectric can be formed on a silicon substrate, and a contact hole can be formed in the dielectric. A portion of the silicon substrate can etched through the contact hole.

### CROSS-REFERENCE TO RELATED APPLICATION

The present application claims the benefit under 35 U.S.C. §119 of Korean Patent Application No. 10-2007-0138914, filed on Dec. 27, 2007, which is hereby incorporated by reference in its entirety.

### BACKGROUND

A trench metal oxide semiconductor field-effect transistor (MOSFET) is a transistor in which a channel is vertically formed and a gate is provided in the form of a trench between source regions.

The trench typically has an outline formed of a thin dielectric such as an oxide layer in a groove of a semiconductor substrate. The trench can be filled with a conductive material such as polysilicon to form a trench gate structure.

A source region is often formed by implanting high concentration ions along both sides of the trench.

### BRIEF SUMMARY

Embodiments of the present invention provide a semiconductor device and a method for manufacturing the same. A contact hole can be provided with excellent characteristics for accepting a contact electrode in a metal oxide semiconductor field-effect transistor (MOSFET) device with a trench type gate structure.

In one embodiment, a method for manufacturing a semiconductor device can comprise: forming a dielectric on a silicon substrate; forming a photoresist pattern on the dielectric; etching the dielectric using the photoresist pattern as a mask to form a contact hole; removing the photoresist pattern; and etching a portion of the silicon substrate through the contact hole to form a trench; wherein the photoresist pattern is removed before etching the portion of the silicon substrate.

In a further embodiment, a method for manufacturing a semiconductor device can comprise: forming a trench in a silicon substrate; forming a gate dielectric inside the trench; forming a gate electrode on the gate dielectric; forming a source region in a portion of the silicon substrate on a side of the trench; forming a dielectric on the silicon substrate; forming a contact hole exposing a portion of the source region in the dielectric; and etching a portion of the silicon substrate through the contact hole using an etching equipment. The etching equipment can be an apparatus for etching an oxide layer. According to an embodiment, forming the contact hole can comprise: forming a photoresist pattern on the dielectric; etching the dielectric using the photoresist pattern as a mask to form the contact hole; and removing the photoresist pattern; and wherein the photoresist pattern is removed before etching the portion of the silicon substrate.

Additionally, certain embodiments of the present invention can etch a silicon substrate using an apparatus for etching an oxide layer thereby reducing manufacturing costs reduce and improving the profile of a contact hole.

The details of one or more embodiments are set forth in the accompanying drawings and the description below. Other features will be apparent from the detailed description, the drawings, and the claims.

### BRIEF DESCRIPTION OF THE DRAWINGS

FIG. 1 is a cross-sectional view of a semiconductor device according to an embodiment of the present invention.

FIGS. 2A-D and 3 are cross-sectional views illustrating a process for forming a contact hole in a semiconductor device according to an embodiment of the present invention.

FIG. 4 is a rendering of an image of a silicon substrate etched by an apparatus for etching silicon in a process for forming a contact hole.

FIG. 5 is a rendering of an image of a silicon substrate etched by an apparatus for etching an oxide layer in a process for forming a contact hole according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Reference will now be made in detail to the embodiments of the present disclosure, examples of which are illustrated in the accompanying drawings.

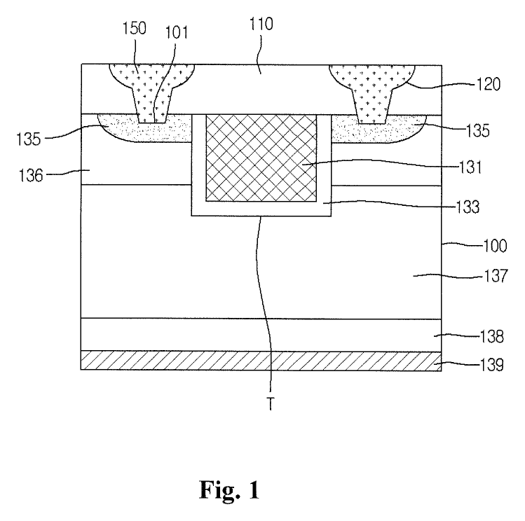

FIG. 1 is a cross-sectional view of a semiconductor device according to an embodiment of the present invention.

Referring to FIG. 1, a trench T can be formed to a predetermined depth in an active region of a silicon substrate 100. A gate dielectric 133 can be formed along the inner wall of the trench T.

A gate electrode 131 can be formed on the gate dielectric 133 inside the trench T. The gate electrode 131 can be formed of any suitable material known in the art, for example, polysilicon.

P-well regions 136 can be formed in the silicon substrate 100 at sides of the trench T. N-type ions can be implanted into an upper portion of each p-well region to form a source region 135. In an embodiment, the n-type ions can be implanted at a high concentration.

A drain region 138 can be formed in a lower portion of the silicon substrate 100 below an n-drift region 137.

A drain electrode 139 contacting the drain region 138 can be formed on a lower side of the silicon substrate 100.

A dielectric 110 can be formed on the silicon substrate 100 having a trench type gate structure. In an embodiment, the dielectric 110 can include an oxide layer.

A contact hole 120 can be formed exposing a portion of the source region 135. The contact hole 120 can be formed through the dielectric 110, and a portion of the source region 135 in the silicon substrate 100. The contact hole 120 can have, for example, a hole-type shape or a trench shape.

A contact electrode 150 can be formed inside the contact hole 120. The contact electrode 150 can be formed of any suitable material known in the art, for example, aluminum.

In a metal oxide semiconductor field-effect transistor (MOSFET) with a trench type gate structure according to embodiments of the present invention, the contact electrode 150 can be formed on the source region 135. Contact electrodes (not shown) can also be formed on the gate electrode 131. When a voltage is subsequently applied to the gate electrode 131, a current can flow from the source region 135 to the drain region 138 located in the lower portion of the silicon substrate 100, thereby allowing a semiconductor device to operate.

The contact hole 120 can have a profile such that the width of the contact hole 120 is smaller at the bottom of the contact hole 120 than at the top of the contact hole 120. In an embodiment, a side of the contact hole can have a gentle slope and then a steep slope as it gets closer to the bottom of the contact hole 120. A trench 101 for the contact hole 120 can be formed by etching a portion of the silicon substrate 100 located in a lower portion of the contact hole 120.

The advantageous profile of the contact hole 120 and the extension of the contact hole 120 using the trench 101 of the silicon substrate 100 can improve device characteristics when a contact electrode 150 is formed in the contact hole 120 including the trench 101.

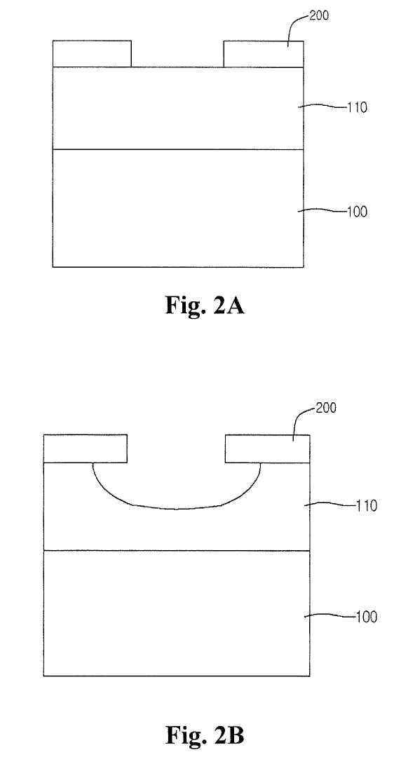

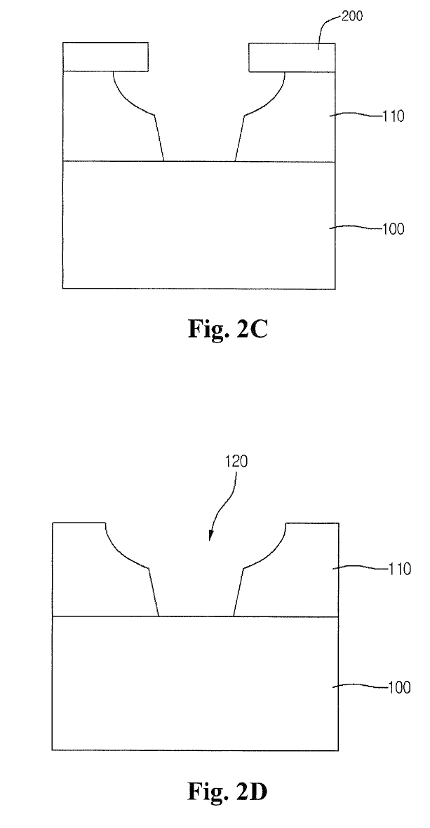

FIGS. 2A-2D and 3 are cross-sectional views illustrating a contact hole forming process in a semiconductor device according to an embodiment of the present invention.

Referring to FIGS. 2A-D, a dielectric 110 can be formed on a silicon substrate 100, and a contact hole 120 can be formed in the dielectric 110.

The contact hole 120 can have any suitable shape, for example, a hole-type shape or a trench shape.

In an embodiment, forming the contact hole 120 in the dielectric 110 can include coating a photoresist layer on the dielectric 110 and exposing and developing regions of the photoresist layer to form a photoresist pattern 200 exposing a contact hole forming region, for example as shown in FIG. 2A.

Referring to FIG. 2B, the dielectric 110 can undergo an etching process using the photoresist pattern 200 as a mask. In an embodiment, the etching process can be performed in an apparatus for etching an oxide layer. Any suitable apparatus for etching an oxide layer known in the art can be used, for example, “Super-e oxide etcher” by AMAT Co.

Referring to FIGS. 2C and 2D, the contact hole 120 formed in the dielectric 110 can have a profile such that the width of the contact hole 120 is smaller at the bottom of the contact hole 120 than at the top of the contact hole 120. In an embodiment, a side of the contact hole can have a gentle slope and then a steep slope as it gets closer to the bottom of the contact hole 120. This can be accomplished by adjusting the etching conditions within the etching apparatus. For example, isotropic etching may be initially conducted and then anisotropic etching may be used to etch the lower portion of the contact hole 120.

The contact hole 120 can expose a portion of the silicon substrate 100 under the dielectric 110.

Referring to FIG. 3, the exposed portion of the semiconductor substrate 100 can be etched to form a trench 101. In an embodiment, the exposed portion of the semiconductor substrate 100 can be etched without using an etch stop layer on the dielectric 110. Accordingly, the photoresist pattern 200 can be removed before etching the substrate.

In a specific embodiment, the exposed portion of the silicon substrate 100 can be etched in an apparatus for etching an oxide layer, instead of an apparatus for etching silicon.

The apparatus for etching an oxide layer used for etching the exposed portion of the silicon substrate 100 can be the same apparatus as the apparatus for etching an oxide layer used to etch the dielectric 110, though embodiments are not limited thereto.

The silicon substrate 100 can be etched along a lower portion of the contact hole 120 to form the trench 101. In an embodiment, the silicon substrate 100 can be etched anisotropically.

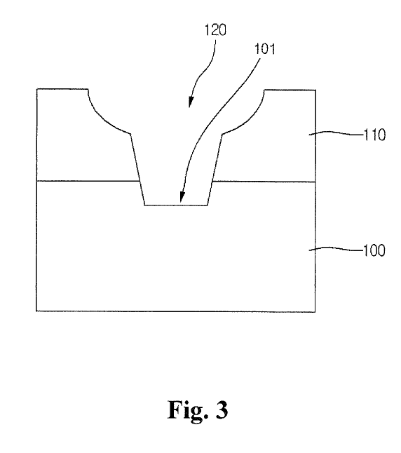

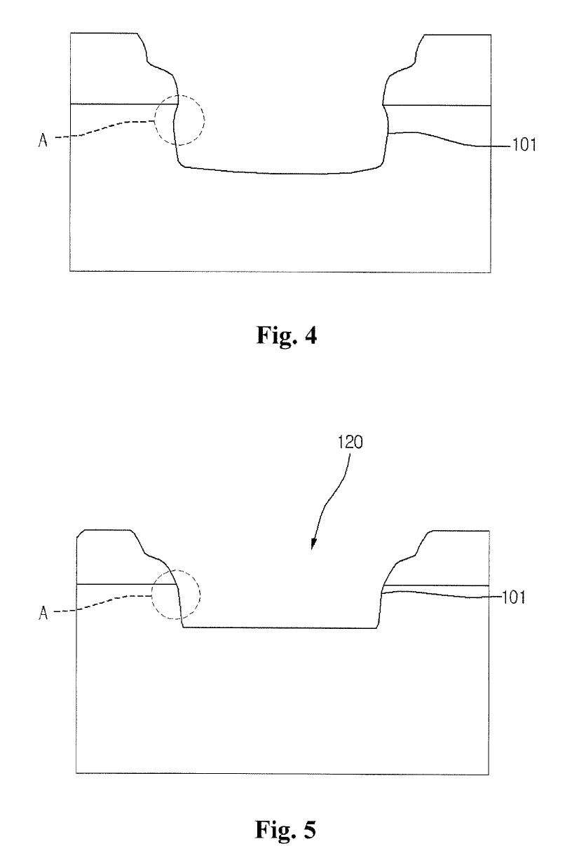

FIG. 4 is a rendering of an image of a silicon substrate etched by a silicon etching apparatus in a process of forming a contact hole, and FIG. 5 is a rendering of an image of a silicon substrate etched by an apparatus for etching an oxide layer in a process of forming a contact hole according to an embodiment of the present invention.

Referring to FIG. 4, a trench profile is shown in the case where an etching process for forming the trench 101 in the silicon substrate 100 is performed using an apparatus for etching silicon, and no etch stop layer, such as a photoresist pattern on the dielectric 110, is used. Accordingly, when the silicon substrate 100 is etched using an etching gas, such as Ar and/or SF₆, the sidewall of the silicon substrate 100 can be damaged, thereby forming the trench 101 with a jar-shaped profile. Since the silicon substrate 100 is etched without a photoresist pattern on the dielectric 110, a passivation layer may not form on a sidewall of the silicon substrate 100 as an etching byproduct. Thus, the sidewall of the silicon substrate 100 can be actively etched (refer to a portion ‘A’ in FIG. 4).

When a jar-shaped trench 101 is formed, a metal layer can fail to completely fill in the contact hole 120 when the metal layer is formed on the dielectric in a process to form a contact electrode in the contact hole 120.

Referring to FIG. 5, to inhibit the formation of a jar-shaped trench 101 in the silicon substrate 100, an apparatus for etching an oxide layer can be used to suppress an isotropic etching effect and allow formation of a passivation layer on the sidewall of the trench 101 of the silicon substrate 100 during an etching process.

Thus, in an embodiment, the silicon substrate 100 can be etched using an apparatus for etching an oxide layer. The etching process can be performed at a pressure of about 30 mTorr or less. In a specific embodiment, O₂ and SF₆ can be used as etching gases. The etching gas ratio of SF₆:O₂ can be from about 1:1 to about 1:2.

When O₂ is used as an etching gas and overflowed, oxygen can form a passivation layer by adsorbing on the sidewall of the silicon substrate 100 being etched.

In an embodiment, HBr etching gas can be specifically excluded from the apparatus for etching an oxide layer during a process of etching the silicon substrate 100.

When the trench 101 is formed in the silicon substrate 100 using an apparatus for etching an oxide layer, damage on the sidewall of the trench 101 can be inhibited, and the contact hole 120 of the silicon substrate 100 and the dielectric 110 can have a desirable shape for accepting a metal layer to form a contact electrode.

That is, in an embodiment, the contact hole 120 in the dielectric 110 can have a profile with a gentle slope in an upper portion and a steep slope in a lower portion. Since a portion of the silicon substrate 100 inside the contact hole 110 can be anisotropically etched, the trench 101 can be formed along a lower sidewall portion of the contact hole 120.

Therefore, undesired defects such as a jar shape can be inhibited inside the contact hole 120 and the trench 101. A metal layer can then be deposited during a subsequent process to a depth of several tens of thousands of Angstroms (Å) in the contact hole 120 of the dielectric 110, thereby securing stable process conditions and device characteristic.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
forming a dielectric on a silicon substrate;
forming a photoresist pattern on the dielectric;
etching the dielectric using the photoresist pattern as a mask to form a contact hole;
removing the photoresist pattern; and
etching a portion of the silicon substrate through the contact hole to form a trench;
wherein the photoresist pattern is removed before etching the portion of the silicon substrate.

2. The method according to claim 1, wherein etching a portion of the silicon substrate comprises using an apparatus for etching an oxide layer.

3. The method according to claim 2, wherein etching a portion of the silicon substrate comprises using SF₆ gas and O₂ gas as etching gases.

4. The method according to claim 1, wherein etching a portion of the silicon substrate comprises using SF₆ gas and O₂ gas as etching gases.

5. The method according to claim 4, wherein an etching gas ratio of SF₆:O₂ is from about 1:1 to about 1:2.

6. The method according to claim 1, wherein etching a portion of the silicon substrate is performed at a pressure of about 30 mTorr or less.

7. The method according to claim 1, further comprising forming a contact electrode in the contact hole after forming the trench.

8. The method according to claim 7, wherein the contact electrode comprises aluminum.

9. The method according to claim 1, wherein etching the dielectric comprises:
performing an isotropic etching for an initial time period using the photoresist pattern as a mask, and
performing an anisotropic etching for a secondary time period using the photoresist pattern as a mask; and
wherein etching a portion of the silicon substrate comprises:
performing an anisotropic etching.

10. The method according to claim 1, wherein the dielectric comprises an oxide layer.

11. A method for manufacturing a semiconductor device, comprising:
forming a trench in a silicon substrate;
forming a gate dielectric inside the trench;
forming a gate electrode in the trench and on the gate dielectric;
forming a source region in a portion of the silicon substrate on a side of the trench;
forming a dielectric on the silicon substrate;
forming a contact hole exposing a portion of the source region in the dielectric; and
etching a portion of the silicon substrate through the contact hole using an apparatus for etching an oxide layer.

12. The method according to claim 11, wherein forming the contact hole comprises:
forming a photoresist pattern on the dielectric;
etching the dielectric using the photoresist pattern as a mask to form a contact hole; and
removing the photoresist pattern;
and wherein the photoresist pattern is removed before etching the portion of the silicon substrate.

13. The method according to claim 12, wherein etching the dielectric comprises:
performing an isotropic etching for an initial time period using the photoresist pattern as a mask, and
performing an anisotropic etching for a second time period using the photoresist pattern as a mask.

14. The method according to claim 11, wherein etching a portion of the silicon substrate comprises using SF₆ gas and O₂ gas as etching gases.

15. The method according to claim 11, wherein etching a portion of the silicon substrate comprises using SF₆ gas and O₂ gas as etching gases.

16. The method according to claim 15, wherein an etching gas ratio of SF₆:O₂ is from about 1:1 to about 1:2.

17. The method according to claim 11, wherein etching a portion of the silicon substrate is performed at a pressure of about 30 mTorr or less.

18. The method according to claim 11, further comprising forming a contact electrode in the contact hole after etching a portion of the silicon substrate.

19. The method according to claim 17, wherein the contact electrode comprises aluminum.

20. The method according to claim 11, wherein the dielectric comprises an oxide layer.
